(19) United States
(12) Patent Application Publication
(10) Pub. No.: US 2015/0380278 A1
(43) Pub. Date: Dec. 31, 2015

(54) HARDWARE FOR THE SEPARATION AND DEGASSING OF DISSOLVED GASES IN SEMICONDUCTOR PRECURSOR CHEMICALS

(71) Applicant: Lam Research Corporation, Fremont, CA (US)

(72) Inventors: Heather Landis, Tigard, OR (US); Adrien LaVoie, Newberg, OR (US); Mohamed Sabri, Beaverton, OR (US)

(21) Appl. No.: 14/320,108

(22) Filed: Jun. 30, 2014

(51) Int. Cl. H01L 21/67; B01D 19/00

(52) U.S. Cl. CPC H01L 21/6715; B01D 19/00

(57) ABSTRACT

An apparatus for degassing gases having large gas molecules, such as argon, from liquids for use in semiconductor processing is provided. The apparatus includes a spool-free tubing in a cylindrical vessel with a removable lid and crystalline window. The apparatus is assembled by removing the lid, connecting the tubing via connectors to an inlet and outlet in the lid, and placing the tubing into the vessel with the lid, and securing the lid.

### BACKGROUND

Various deposition techniques of thin films including plasma-enhanced chemical vapor deposition (PECVD) are important in the fabrication of very large scale integrated circuits. In some of these methods, gaseous or liquid precursor chemicals are delivered to gas dispersion showerheads at deposition stations in a reactor chamber, where they react with a silicon substrate. If the chemical is delivered in liquid form, it passes through a vaporizer before it enters the reaction chamber. Liquid delivery systems are of particular importance to the operation of semiconductor substrate processing reactors.

### SUMMARY

Provided herein are apparatuses for removing dissolved gas from a liquid and methods of assembling such apparatuses. One aspect is an apparatus for removing dissolved gas from a liquid may include a cylindrical vessel, a structure, and a liquid mass flow controller. The vessel may include a low pressure connection, and a lid positioned on a top panel of the vessel, such that the lid includes an inlet, and an outlet. The structure may include a material impermeable to the liquid and permeable to the gas, and the structure coiled without a spool. The structure is less than about 10 feet in length, may be inside the vessel, and is connected to the inlet and outlet. The structure may remove at least some of the dissolved gas from the liquid during passage of the liquid from the inlet to the outlet. The liquid mass flow controller may be connected to the outlet to dispense the liquid after removal of the dissolved gas by the structure.

In some embodiments, the structure is connected to the inlet and outlet via connectors. In various embodiments, the lid is removable. The lid may also include a transparent encasing.

In various embodiments, the vessel has a height of about 4 inches, and upper and lower faces having a diameter between about 2.5 and about 3.0 inches. The vessel may also include a cover on a face of the vessel, such that the cover includes a window having crystalline material. In some embodiments, the crystalline material is selected from the group consisting of quartz, sapphire, and plastics including though not limited to polyethylene, polypropylene, polystyrene, and polyterephthalate.

In some embodiments, the apparatus further includes a vacuum port, spill sensor port, and spill sensor funnel. The spill sensor funnel may be positioned on a bottom panel of the vessel.

In various embodiments, the gas removed from the liquid has an atomic radius greater than about 50 picometers, such as argon. In some embodiments, the material is a fluoroplastic selective to molecules or atoms having an atomic radius or molecular diameter greater than about 50 picometers. The structure may be about 5 feet in length and in some embodiments, the material may be non-elastic.

Another aspect is a method of assembling an apparatus to remove a dissolved gas from a liquid by removing a removable lid from a vessel where the lid includes an inlet and an outlet; coiling a structure without a spool, where the structure includes a material impermeable to the liquid and permeable to the gas; connecting the ends of the structure to the inlet and the outlet of the removable lid to form the assembled lid with the structure; and inserting the assembled lid with the structure into the vessel, such that the structure is inside the vessel and is connected to the inlet and outlet of the vessel, and the structure removes at least some of the dissolved gas from the liquid during passage of the liquid from the inlet to the outlet.

In various embodiments, the gas is argon. In some embodiments, the lid includes a crystalline window. In some embodiments, the ends of the structure are connected to the inlet and outlet via connectors.

These and other aspects are described further below with reference to the drawings.

### BRIEF DESCRIPTION OF THE DRAWINGS

FIG. 1 is a schematic representation of a cross-section frontal view of an apparatus in accordance with various embodiments.

FIG. 2 is a schematic representation of a frontal view of an apparatus in accordance with various embodiments.

FIG. 3 is a schematic representation of a cross-section frontal view of an apparatus assembled in accordance with various embodiments.

FIG. 4 is a schematic representation of a top view of an apparatus in accordance with various embodiments.

FIG. 5 is a schematic representation of a cross-section of a side view of an apparatus in accordance with various embodiments prior to full assembly.

FIG. 6 is a schematic representation of a cross-section of a side view of an assembled apparatus in accordance with various embodiments.

FIG. 7 is a schematic representation of a tool including an apparatus in accordance with various embodiments.

FIGS. 8, 9A, 9B, and 10 are graphs of experimental results for diffusion rates of gases using material in accordance with various embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor processing systems including various reactors and tools often require the delivery of a liquid to a reactor chamber for deposition of various thin films. For example, liquid precursors may be delivered to a chamber through a showerhead to deposit layers for PECVD. Liquid precursors to be delivered may be stored using various methods, such as in a vessel containing the liquid and a pressurized gas. In some liquid delivery systems, a carrier gas is used to help deliver a liquid through various modules in a reactor. However, in these circumstances, some gas may dissolve in the liquid. Thus, such liquids often are degassed prior to delivery into the reactor chamber.

Conventional liquid degassing systems often include a housing with an internal vessel. The vessel may be cylindrical, having flat panels on the front and back end of the vessel, such that the back end is connected to a mounting plate and the front end includes a cover having a window. The window has conventionally been made of plastic or other polymers, and is used to view the degassing process. An inlet and an outlet are conventionally positioned at the top of the vessel on the curved wall of the cylindrical vessel. To assemble the module, the cover on the front panel is opened and the user must insert the tubing from the front opening. The user then works within the vessel to connect the tubing to the inlet, coil it around a spool positioned in the vessel, and connect the tubing to the outlet. After full assembly of the tubing, the cover is closed. Conventional material used in the tubing included amorphous fluoroplastic material having a high permeability to small gas molecules, but no permeability to large gas molecules. Due to the nature of the fluoroplastic used, the tubing required to fully degas a liquid was typically more than 50 feet, for example 66 feet, in length. The vessel dimensions and volume, however, could not optimally accommodate 66 feet of tubing, and as a result, tubing wound around the spool often overlapped with existing tubing on the spool, thereby mitigating effective degassing of the liquid in subsequent processing. Example dimensions of vessels used in conventional degassing systems include a depth between 3.5 and 4 inches, a width of 3.5 inches, and a height of 4.5 inches.

Since the conventional liquid delivery systems are typically only suitable for degassing small gas molecules from liquids, such as helium, these systems are unable to accommodate evolving industry needs. As the industry moves from the use of helium as a carrier gas to gases such as argon which has larger gas molecules, conventional liquid delivery systems are unsuitable because the gases are unable to permeate through the material used to degas the liquid.

Provided herein is a spool-free, efficient degassing apparatus for degassing large gas molecules from liquids for use in semiconductor substrate processing. The apparatus has improved assembly operations, shorter tubing, highly efficient degassing of both small and large gas molecules, a smaller, more compact design, and other structural innovations resulting in performance improvement, as further described below.

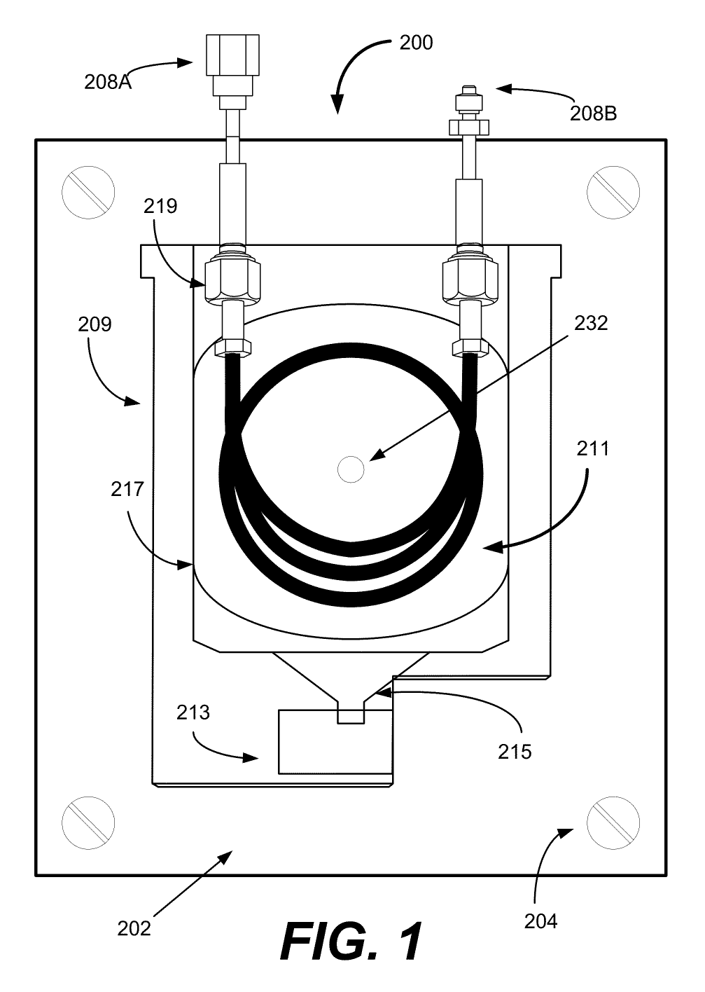

FIG. 1 is a schematic representation of the front view of a cross-section of an apparatus 200 in accordance with various embodiments. The apparatus includes a housing 209 having an inner portion, or a vessel 217, and the housing is connected to the mounting plate 202. The apparatus 200 can be mounted to a tool (not shown) using mounting screws 204. The housing 209 includes a vacuum port 232, which may be compatible to any suitable vacuum or any conventional vacuum. The vessel 217 may have smaller dimensions than conventional degassing modules. Example dimensions may include a depth of about 2.5 inches, a width of about 3.0 inches, and a height of about 4 inches. The vessel 217 is cylindrical, having rounded internal sidewalls at least on the left and right sidewalls and flat panels at the top and bottom, such that the bottom panel includes an opening to a spill sensor funnel 215. The spill sensor funnel 215 includes an opening to a spill sensor port 213. The spill sensor port 213 may be compatible with any suitable spill sensor or any conventional spill sensor. Spill sensors may detect a liquid leak such as if liquid leaks from a structure or tubing 211.

The structure or tubing 211 is coiled without a spool and connected to inlet 208A and outlet 208B via connectors 219. The inlet 208A and outlet 208B of housing 209 may include any commercially available fittings for providing a gas, liquid, and vacuum tight seal. In some embodiments, the inlet 208A and outlet 208B may be identical. In some embodiments, fittings may include a stainless steel sleeve inside an end of a conduit with an O-ring adjacent to an internal member inside a female fitting. The female fitting may mate with a male fitting such that the O-ring is compressed onto the conduit when the fitting is tightened to form an air-tight seal. The male fitting may be welded to a lid of the housing 209.

The tubing 211 is wound such that the tubing does not overlap. The tubing 211 may be packed with material highly permeable to large molecules. “Large” molecules can be defined as having a diameter greater than about 50 picometers. Some “large” molecules may have an atomic radius or a molecular diameter greater than about 50 picometers. One category of “large” molecules may include noble gases having an atomic radius greater than about 50 picometers. Example large gas molecules include argon (Ar) and nitrogen (N₂). Since the material is permeable to large molecules, the material is also permeable to smaller molecules such as helium (He). Example materials used in tubing 211 include fluoroplastics, such as the DuPont™ Teflon® AF. The material is a glass-like brittle non-elastic material. In some embodiments, the material may be permeable to argon such that the rate of diffusion of argon is at least 0.05 psi per second. Due to the higher rate of diffusion, shorter tubing may be used. Therefore, the tubing 211 may have a length less than about 10 feet in length, or about 5 feet in length, and an internal diameter of about 0.0625 inch.

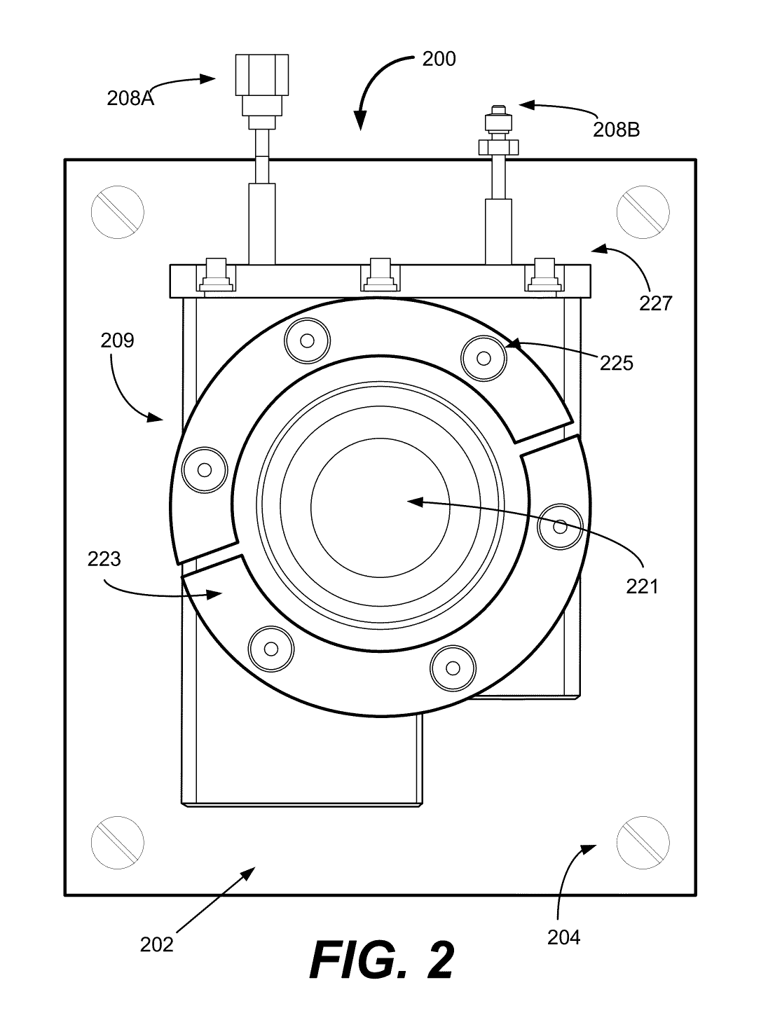

FIG. 2 is a schematic depiction of a frontal view of the apparatus with the cover 223 closed and the lid 227 also closed. The cover 223 may be secured using cover screws 225, or other suitable fasteners, and may include a window 221 made of a transparent material such that a user may view the degassing process within the housing 209. The material may be a crystalline material, such as sapphire, quartz, or plastics including but not limited to polyethylene, polypropylene, polystyrene, and polyterephthalate. The crystalline material reduces discoloration of the window 221 due to exposure to chemicals in the degassing process, and therefore is more durable than the conventional polymeric material used in windows. The lid 227 may be secured on the housing 209 using screws, or other suitable fasteners, such that the lid is attached to the inlet 208A and outlet 208B.

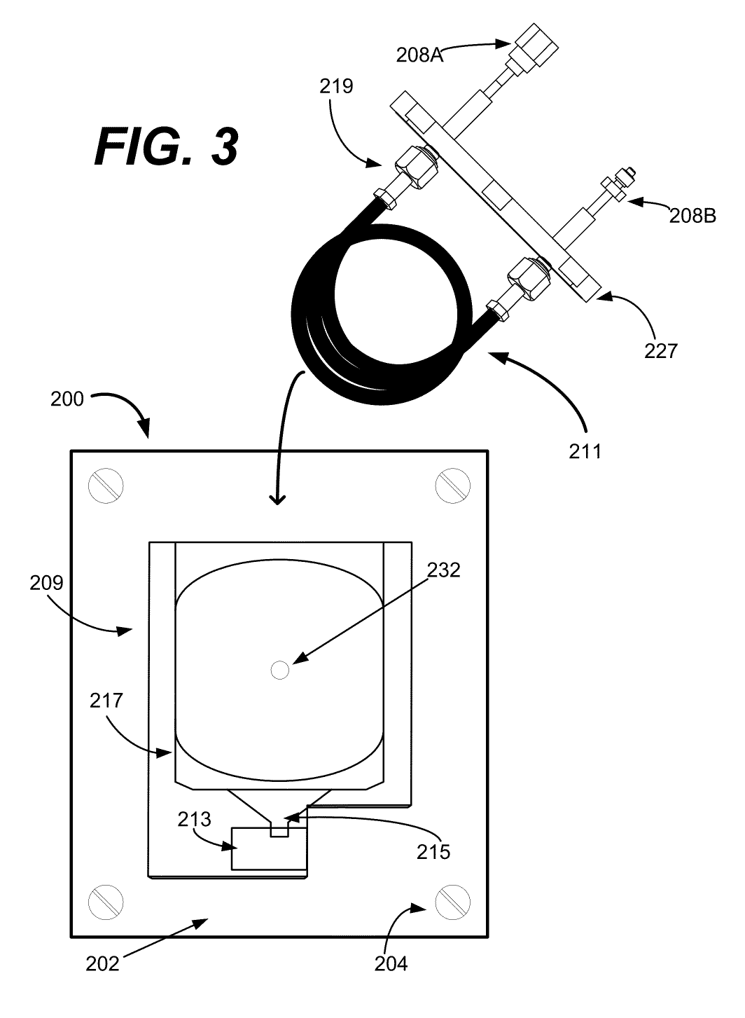

FIG. 3 is a schematic depiction of features of the apparatus 200 being assembled from a frontal view. The lid 227 may be connected to the inlet 208A and outlet 208B, which may be secured to connectors 219 such that the tubing 211 is connected to the connectors 219 using a custom fitting. In many embodiments, the connectors 219 are screw-on connectors. The tubing 211 may be attached to the connectors 219 and coiled at a location separate from the apparatus 200, such as on a bench or working station. Since the material used for the tubing may be brittle and glass-like, connecting the tubing 211 to the connectors 219 at a location separate from the apparatus 200 allows the tubing 211 to be connected reliably with little or no torsional stress on the tubing 211. The lid 227 including the connectors 219, tubing 211, inlet 208A and outlet 208B may be placed over the housing 209 such that the tubing 211 is placed in the vessel 217 and positioned over the spill sensor funnel 215, yielding an assembled apparatus 200 such as the one depicted in FIG. 1. Note that the structure of apparatus 200 yields a reduced footprint due to the smaller size and incorporates enhanced ergonomics for ease in assembly.

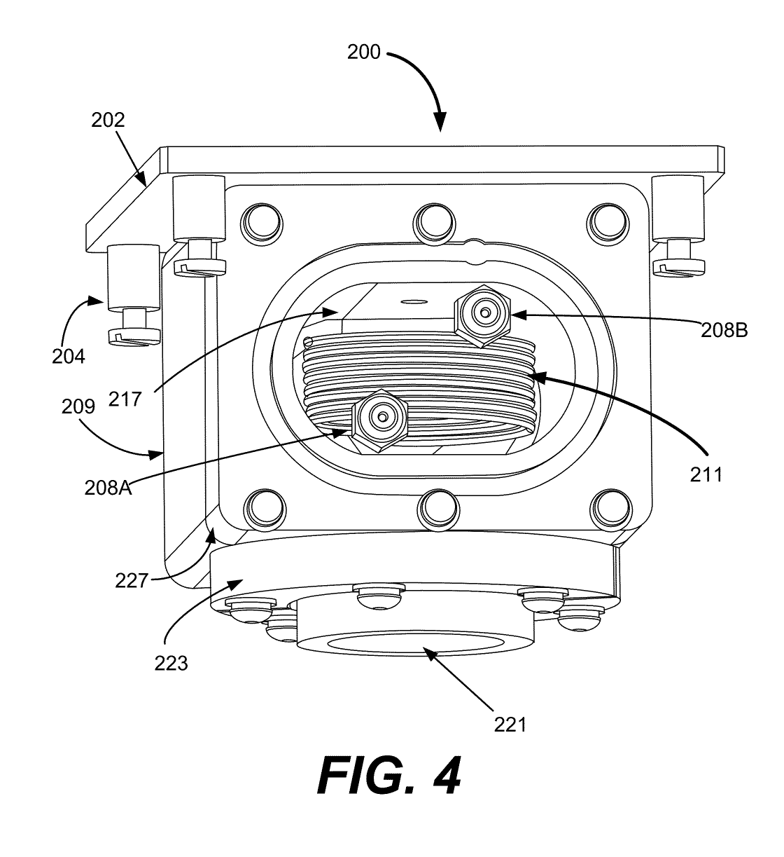

FIG. 4 is a schematic representation of a top view of the apparatus 200 in accordance with various embodiments. As shown, the housing 209 is attached to the mounting plate 202 which is attached to a tool (not shown) by mounting screws 204. The housing 209 includes a vessel 217 with lid 227 and the tubing 211 sitting inside the vessel 217. The lid 227 is secured by six screws on the lid 227 and the tubing 211 is connected to inlet 208A and outlet 208B which extrude outwards towards the viewer. As shown, the lid 227 may have a transparent encasing such that the user may view the degassing process from above. The housing 209 also includes a cover 223 including a window 221 to view the degassing process from the front of the apparatus 200.

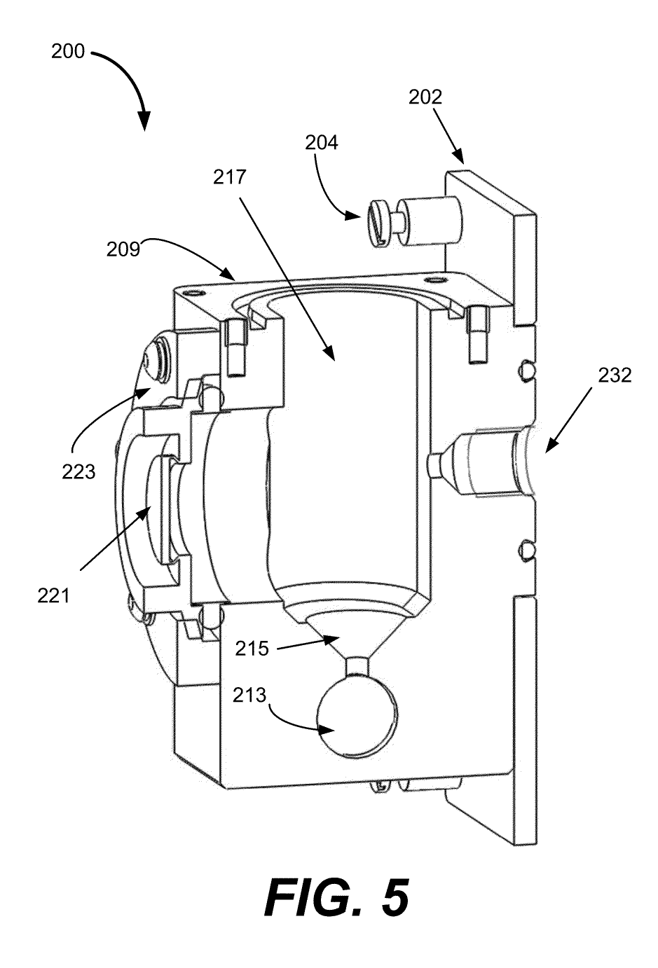

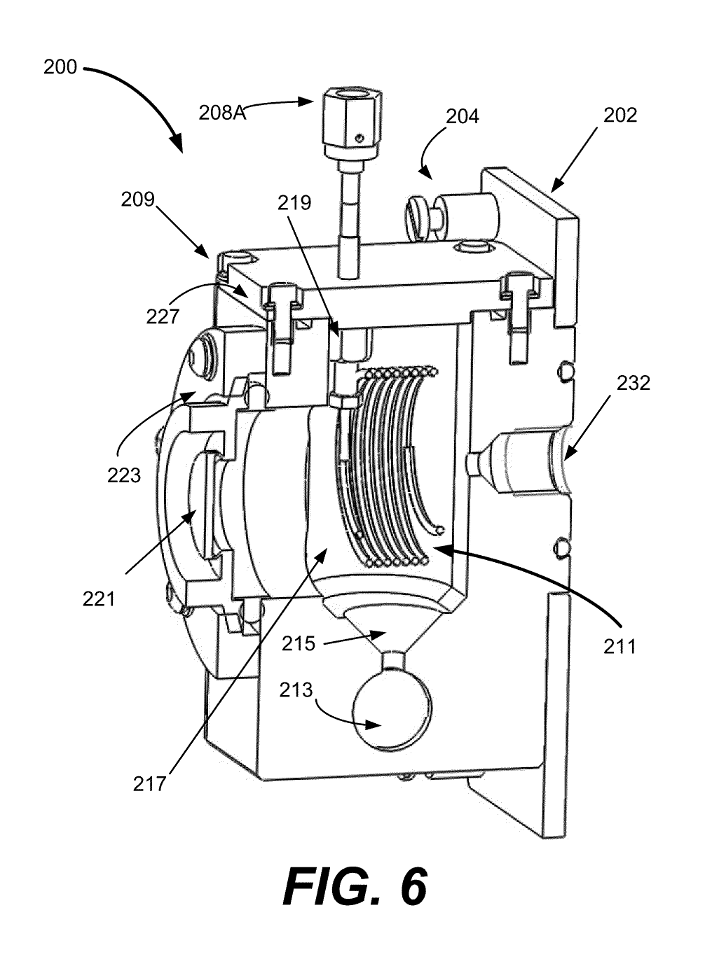

FIG. 5 is a schematic representation of a side view cross section of the apparatus 200 without the lid and tubing secured on the apparatus 200. As shown, the housing 209 is attached to the mounting plate 202, which may subsequently be mounted to a tool (not shown) by mounting screws 204. The housing 209 includes a vacuum port 232 that such that the vacuum may be incorporated from the tool through the mounting plate 202 and to the housing 209. The housing 209 includes the vessel 217 having a cylindrical shape with an oval opening at the top and an oval bottom with an opening to a spill sensor funnel 215. The spill sensor funnel 215 opens to a spill sensor port 213 where a spill sensor (not shown) may be inserted. The housing 209 also includes a cover 223, which includes a window 221. The cover is positioned on the front of the housing 209. In FIG. 6, the tubing 211 has been assembled with the lid 227, and the tubing 211 is inserted with the lid 227 such that the lid 227 is securely positioned on top of the housing 209 by screws. The cross-sectional view also shows inlet 208A on the lid 227. In many embodiments, the inlet 208A and outlet 208B are welded to the lid 227.

During operation, a liquid may be displaced in a supply source by pressurized gas, such as a gas having large molecules. In some embodiments, the gas is argon or helium. The liquid precursor, such as tetraethyl orthosilicate (TEOS), may flow through inlet 208A and through the tubing 211 at a pressure higher than the low pressure that surrounds the tubing 211. Since the tubing 211 includes material permeable to large gas molecules, and since there is a pressure differential across the walls of the tubing 211, the large gas molecules diffuses out of the liquid and through the tube walls and into the vessel 217. The large gas molecules in vessel 217 are then pumped away through the vacuum port 232. The liquid then flows into a liquid mass flow controller through outlet 208B, where it is precisely metered and controlled due to the absence of bubbles of the gas. The outlet of the liquid mass flow controller may be connected to the inlet of a deposition system, such as a PECVD system, to perform deposition of the liquid onto wafers to a precisely controlled and reproducible thickness. If there is a rupture in tubing 211, the liquid in vessel 217 flows through the spill sensor 215 and triggers a device inserted into the spill sensor port 213, thereby alarming the user.

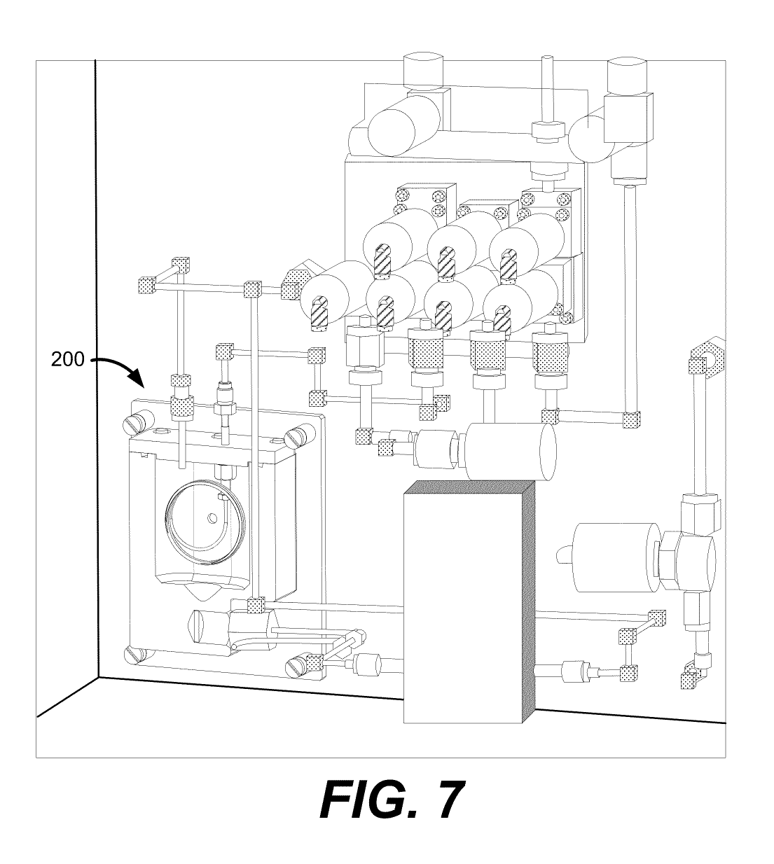

FIG. 7 is a schematic illustration of a section of a tool where the degassing apparatus 200 is positioned. As shown, the mounting plate is mounted on the wall of the tool and the inlets, outlets, and spill sensor are all connected to various conduits of the tool. The apparatus 200 is connected to a liquid mass flow controller via the outlet and the liquid mass flow controller dispenses liquid after removal of the dissolved gas in the degassing structure.

The apparatus disclosed herein is highly efficient and able to degas large gas molecules from liquids, expanding the options for carrier gases used in deposition processes. The apparatus permits delivery of a liquid at a uniform pressure for a user specified flow rate. Static gas pressure displacement is a very economical and particle-free method of pressurizing liquids. Liquid flow in a system according to this invention is stable and uninterrupted until the supply source vessel is almost empty. Since the liquid being delivered is particle-free and without any dissolved gas after leaving the degas module, the liquid can be metered very precisely by the liquid mass flow controller.

### EXPERIMENTAL

### Experiment 1: Helium Diffusion

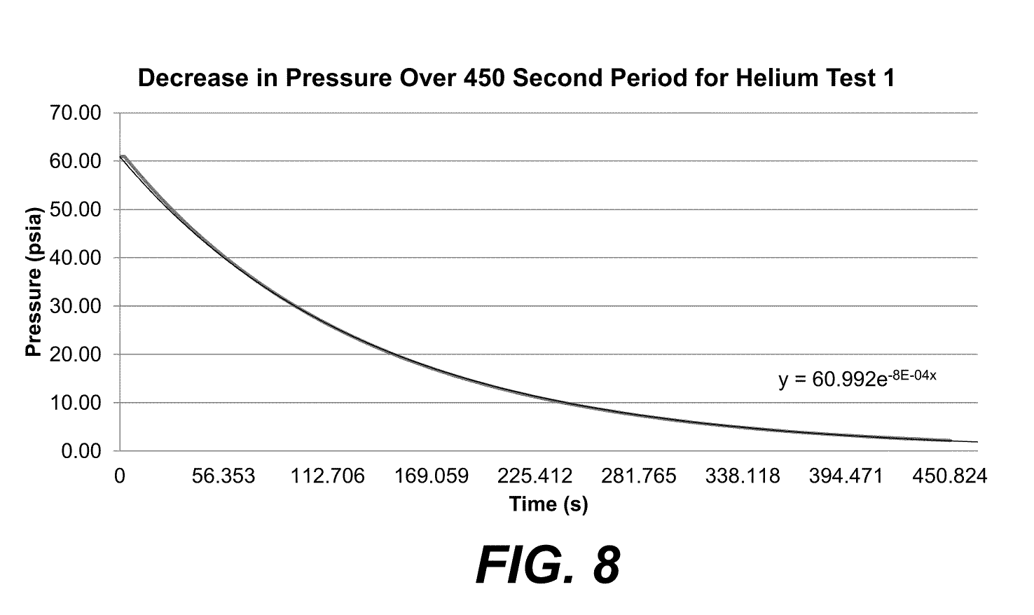

An experiment was conducted to determine the diffusion rate of helium using fluoroplastic material suitable for degassing large gas molecules, which may be used in an apparatus as described in the disclosed embodiments. The material used in this experiment was DuPont™ Teflon® AF. The experiment was conducted by setting up a membrane made of the material between two chambers. The first chamber included about 60 psi of helium, while the second chamber was in a vacuum. The experiment was conducted to determine the pressure of the first chamber as the gas diffused through the amorphous fluoroplastic material to the second chamber. Pressure was measured over 450 seconds, and FIG. 8 depicts an example of the curve showing the pressure versus time for helium diffusion. The results from three trials are presented in Table 1 below.

TABLE 1
Helium Diffusion

| | Pressure Initial | | Pressure After | Average Rate |
|---|---|---|---|---|
| Trial | (psia) | Time | (psia) | (psi drop/sec) |
| 1 | 60.96936 | 450 sec | 2.190898 | 0.130619 |
| 2 | 60.96384 | 450 sec | 2.068667 | 0.130878 |
| 3 | 60.94240 | 450 sec | 1.992911 | 0.130998 |

As shown in FIG. 8 and in Table 1 above, the material is suitable for degassing helium at a reasonable rate of diffusion.

### Experiment 2: Argon Diffusion

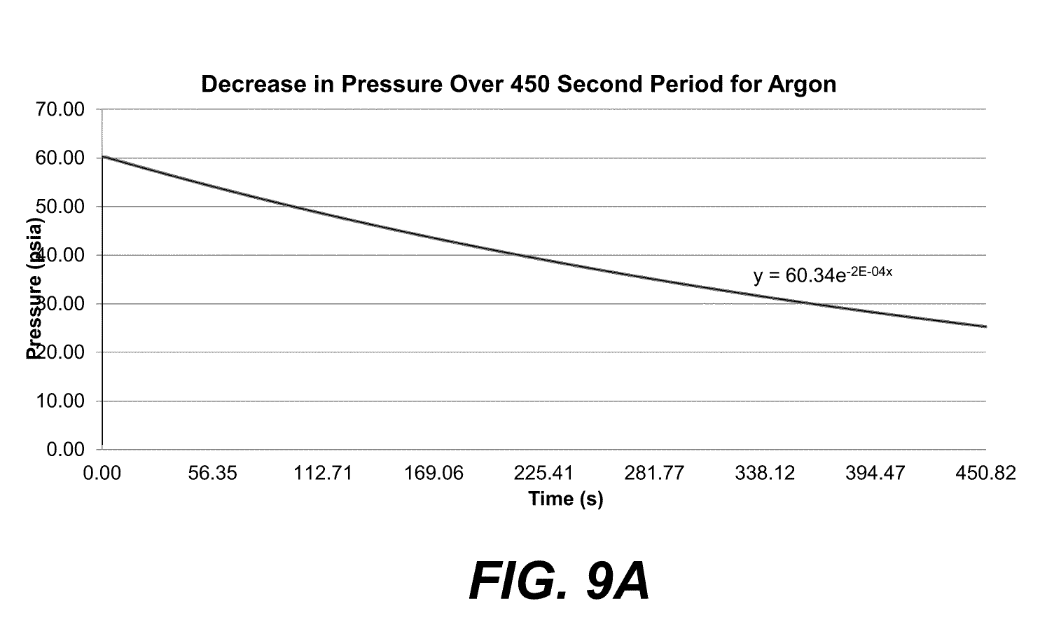

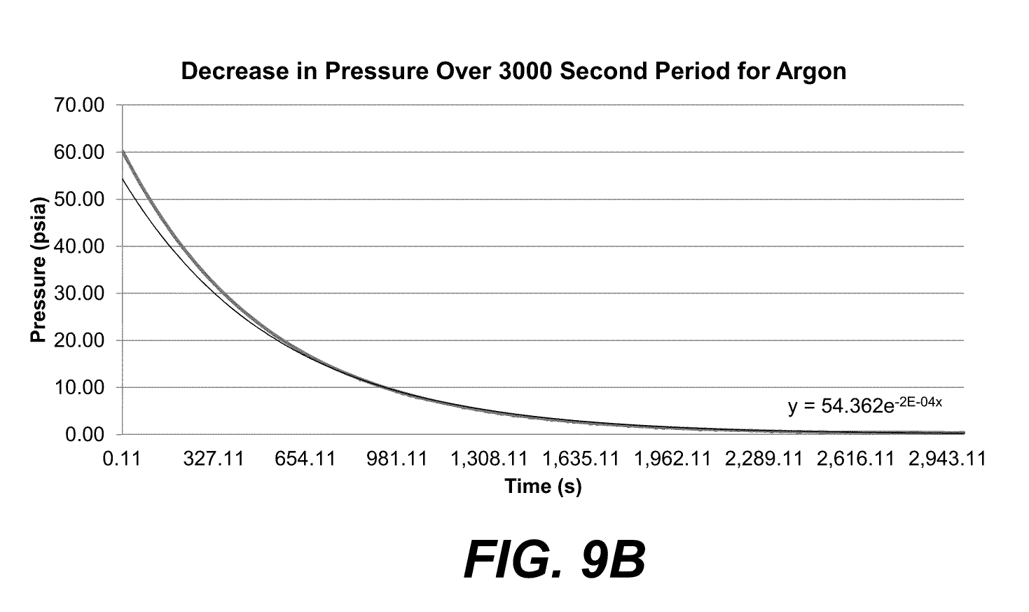

An experiment was conducted to determine the diffusion rate of argon using fluoroplastic material suitable for degassing large gas molecules, which may be used in an apparatus as described in the disclosed embodiments. The material used in this experiment was DuPont™ Teflon® AF. The experiment was conducted by setting up a membrane made of the material between two chambers. The first chamber included about 60 psi of argon, while the second chamber was in a vacuum. The experiment was conducted to determine the pressure of the first chamber as the gas diffused through the amorphous fluoroplastic material to the second chamber. Pressure was measured over 450 seconds for the first trial and over 3000 seconds for the second trial, and FIGS. 9A and 9B depict the pressure versus time graphs for argon diffusion for each trial respectively. The results from three trials are presented in Table 2 below.

TABLE 2
Argon Diffusion

| | Pressure Initial | | Pressure After | Average Rate |
|---|---|---|---|---|
| Trial | (psia) | Time | (psia) | (psi drop/sec) |
| 1 | 60.13267 | 450 sec | 25.28093 | 0.077448 |
| 2 | 60.13267 | 3000 sec | 0.3500652 | 0.0199275 |

As shown in FIGS. 9A and 9B and in Table 2 above, the material used is permeable to argon at a reasonable rate of diffusion. The experimental results show that use of this material in tubing for a degassing apparatus as described in the disclosed embodiments would be effective to degas argon.

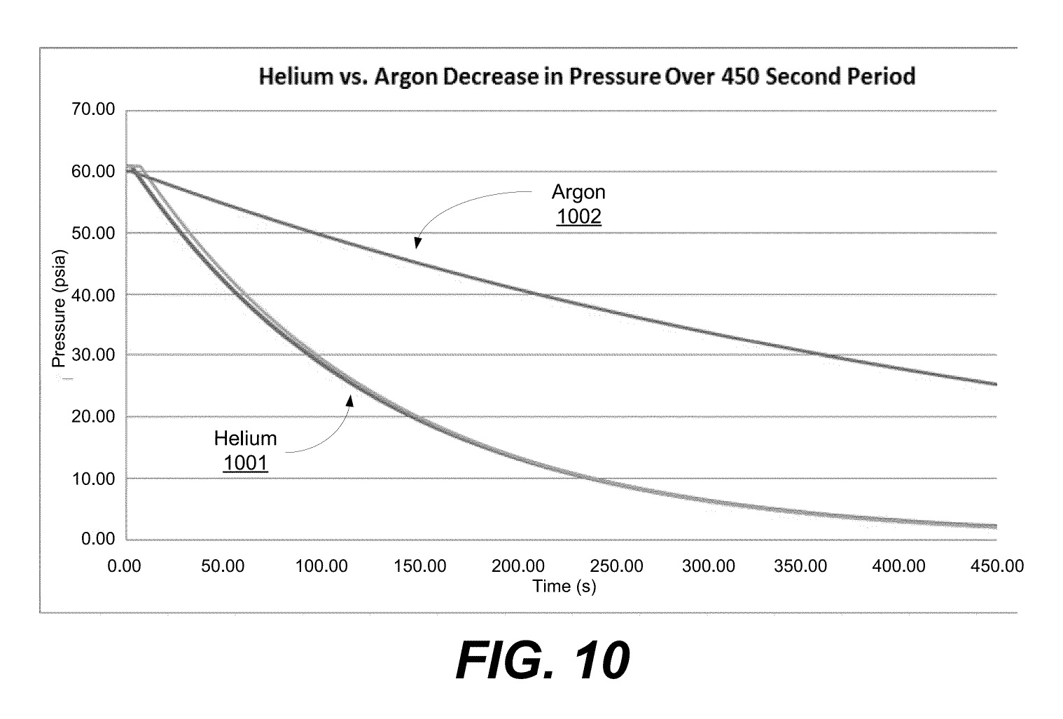

FIG. 10 is a graph comparing the relative rate of diffusion between helium 1001 and argon 1002. As depicted, helium diffuses at a rate faster than that of argon, but the rate of diffusion of argon is sufficiently high such that the material may be used as an effective degasser. As compared to conventional material used in degassing systems where argon only diffused after a time longer than 3000 seconds or argon did not diffuse at all, these experimental results show substantial improvement to degassing large gas molecules and the materials disclosed herein can effectively be used in degassing modules.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. An apparatus for removing dissolved gas from a liquid comprising:
a cylindrical vessel, the vessel comprising:
a low pressure connection, and
a lid positioned on a top panel of the vessel, the lid comprising an inlet, and an outlet;
a structure comprising
a material impermeable to the liquid and permeable to the gas, the structure coiled without a spool,
wherein the structure is less than about 10 feet in length,
wherein the structure is inside the vessel and is connected to the inlet and outlet, and
wherein the structure removes at least some of the dissolved gas from the liquid during passage of the liquid from the inlet to the outlet; and
a liquid mass flow controller connected to the outlet, the liquid mass flow controller dispensing the liquid after removal of the dissolved gas by the structure.

2. The apparatus of claim 1, wherein the structure is connected to the inlet and outlet via connectors.

3. The apparatus of claim 1, wherein the lid is removable.

4. The apparatus of claim 1, wherein the lid comprises a transparent encasing.

5. The apparatus of claim 1, wherein the vessel has a height of about 4 inches, and upper and lower faces having a diameter between about 2.5 and about 3.0 inches.

6. The apparatus of claim 1, wherein the vessel further comprises a cover on a face of the vessel, the cover comprising a window, wherein the window comprises crystalline material.

7. The apparatus of claim 6, wherein the crystalline material is selected from the group consisting of quartz, polyethylene, polypropylene, polystyrene, polyterephthalate, and sapphire.

8. The apparatus of claim 1, wherein the apparatus further comprises a vacuum port, spill sensor port, and spill sensor funnel.

9. The apparatus of claim 8, wherein the spill sensor funnel is positioned on a bottom panel of the vessel.

10. The apparatus of claim 1, wherein the gas removed from the liquid has an atomic radius greater than about 50 pm.

11. The apparatus of claim 1, wherein the structure is about 5 feet in length.

12. The apparatus of claim 1, wherein the gas is argon.

13. The apparatus of claim 1, wherein the material is a fluoroplastic selective to molecules or atoms having an atomic radius or molecular diameter greater than about 50 pm.

14. The apparatus of claim 1, wherein the material is non-elastic.

15. A method of assembling an apparatus to remove a dissolved gas from a liquid, comprising:
removing a removable lid from a vessel, the lid comprising an inlet and an outlet;
coiling a structure without a spool, the structure comprising a material impermeable to the liquid and permeable to the gas;
connecting ends of the structure to the inlet and the outlet of the removable lid to form the assembled lid with the structure; and
inserting the assembled lid with the structure into the vessel,
wherein the structure is inside the vessel and is connected to the inlet and outlet of the vessel, and
wherein the structure removes at least some of the dissolved gas from the liquid during passage of the liquid from the inlet to the outlet.

16. The method of claim 15, wherein the gas is argon.

17. The method of claim 15, wherein the lid comprises a crystalline window.

18. The method of claim 15, wherein the ends of the structure are connected to the inlet and outlet via connectors.
